(19) United States
(12) Patent Application Publication
(10) Pub. No.: US 2010/0207679 A1
(43) Pub. Date: Aug. 19, 2010

(54) Conduction switching circuit, conduction switching circuit block, and operating method of conduction switching circuit

(75) Inventor: Tomonori Okashita, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/656,784

(22) Filed: Feb. 16, 2010

(30) Foreign Application Priority Data
Feb. 19, 2009 (JP) 2009-036228
Jan. 29, 2010 (JP) 2010-018550

(51) Int. Cl. H03K 17/687

(52) U.S. Cl. 327/436

(57) ABSTRACT

An object is to provide a conduction switching circuit, an operation method of a conduction switching circuit, and a conduction switching circuit block, which can prevent a leakage of a high frequency signal without insertion loss of a reactance. A conduction switching circuit includes a first MOSFET, a second MOSFET connected to the first MOSFET via a first node, and a first control terminal connected to the first node. The first MOSFET and the second MOSFET are provided so as to be electrically connected in series at ON state. The first control terminal is configured to apply a voltage to the first node so that capacitance of the first MOSFET and the second MOSFET is decreased when the first MOSFET and the second MOSFET are OFF state.

### INCORPORATION BY REFERENCE

This patent application claims a priority on convention based on Japanese Patent Application No. 2009-036228 and 2010-018550. The disclosure thereof is incorporated herein by reference.

### BACKGROUND OF THE INVENTION

1. Field of the Invention

The present invention relates to a conduction 0switching circuit, a conduction switching circuit block, and an operating method of the conduction switching circuit.

2. Description of Related Art

In recent years, in a mobile communication apparatus such as a portable telephone terminal and the like, an electromagnetic wave of a high frequency in a GHz band is used as a carrier wave. A semiconductor switch (a conduction switching circuit) is used in the mobile communication apparatus. As the semiconductor switch, a GaAs field effect transistor is typically used. However, with advance of a microstructure technique in recent years, MOSFET (Metal-Oxide-Semiconductor Field-Effect Transistor) is gradually used.

FIG. 1 is a circuit diagram showing one example of the MOSFET. This MOSFET 100 is arranged such that a first terminal 101 is electrically connected to a second terminal 102 at an ON state. In the MOSFET 100, a drain is connected to the first terminal 101, and a source is connected to the second terminal 102. Also, a gate of the MOSFET 100 is connected to a control terminal 103 for controlling a gate voltage, via a first resistor 104. A back gate of the MOSFET 100 is connected to the ground via a second resistor 105.

FIG. 2 shows an equivalent circuit at the ON state. At the ON state, the first terminal 101 and the second terminal 102 are electrically connected. At this time, the MOSFET 100 can be regarded as a resistor.

FIG. 3 shows an equivalent circuit of the MOSFET at an OFF state. In the MOSFET, PN junction diodes are respectively included, between the back gate and the source and between the back gate and the drain. Thus, at the OFF state, a junction capacitance C3 is generated between the drain and the back gate, and a junction capacitance C4 is generated between the source and the back gate. Also, an overlap capacitance C1 is generated between the drain and the gate via a gate insulating film, and an overlap capacitance C2 is also generated between the source and the gate. At the OFF state, there is a case that a high frequency signal is leaked through the capacitance C1 to C4.

In FIG. 3, when the first resistor 104 and the second resistor 105 are sufficiently large, the gate end and the back gate end can be considered to be opened. As a result, as shown in FIG. 4, the capacitance C1 to C4 can be represented as one capacitance. This one capacitance (equivalent interrupting capacitance) can be considered to be a performance index that represents a leakage property of the high frequency signal at the OFF state.

A technique for decreasing the equivalent interrupting capacitance is described in Japanese Patent Publication (JP-P 2006-332416A). In JP-P 2006-332416A, a semiconductor device is described. The semiconductor device has a source and a drain of a second conductive type, which are formed in a well of a first conductive type. At the OFF state, voltages are applied to the source and the drain from the control terminal so that PN junctions included between the source and the well and between the drain and the well are reverse-biased.

In addition, as the techniques that can be known by the inventor, Japanese Patent No. 2964975, Japanese Patent Publication (JP-P 2007-214825A), and Japanese Patent Publication (JP-P 2006-121217A) are cited.

### SUMMARY OF THE INVENTION

FIG. 5 is a circuit diagram showing the semiconductor device described in the JP-P 2006-332416A. As shown in FIG. 5, one of a source and a drain in the MOSFET 100 is connected to a control terminal 110 via a resistor 106. Also, the other one of the source and the drain is connected to the control terminal 110 via a resistor 107.

FIG. 6 is an equivalent circuit showing the semiconductor device at the OFF state, which is described in JP-P 2006-332416A. As shown in FIG. 6, at the OFF state, the MOSFET 100 is represented as an equivalent interrupting capacitance. At the off state, voltages are applied to the source and the drain from the control terminal 110 so that PN junctions included between the source and the well and between the drain and the well are reverse-biased. As a result, the equivalent interrupting capacitance is decreased to prevent the leakage of the high frequency signal. Here, in order to apply the voltage to the source and the drain, the source and the drain should be separated from external terminals (the first terminal 101 and the second terminal 102), from an aspect of a direct current. For this reason, as shown in FIG. 5, a capacitor 108 is inserted between the external terminal 101 and the MOSFET 100, and a capacitor 109 is inserted between the external terminal 102 and the MOSFET 100.

On the other hand, FIG. 7 is an equivalent circuit showing the semiconductor device described in FIG. 5 at the ON state. As shown in FIG. 7, at the ON state, the capacitors (108, 109) for cutting the direct current exist. Accordingly, an insertion losses caused by reactance of the capacitors (108, 109) is generated.

In order to decrease the reactance, a capacity value of the capacitors should be increased, and it becomes difficult to miniaturize the semiconductor device. For example, it is supposed that a resistance of the MOSFET 100 at the ON state is 100Ω. At this time, the reactance requested for each of the capacitors 108, 109 is assumed to be 5Ω or less. Here, when the frequency of a high frequency signal passing to the second terminal 102 from the first terminal 101 is 2.4 GHz based on the ISM band, the capacity value requested for each of the capacitors 108, 109 becomes 13 pF. In such case, the capacitors can be formed in the semiconductor device, although an area of the semiconductor device is increased. However, when the frequency of the high frequency signal is 800 MHz, the capacity value requested for each capacitor becomes 40 pF. Also, when the frequency of the high frequency signal is 70 MHz based on an FM signal, the requested capacity value becomes 450 pF. Also, for example, in a case of using as an SPDT (Single-Pole-Double-Through) switch, 8 capacitors are required in one chip. In this way, depending on the frequency of the high frequency signal and the number of the requested capacitors, it becomes difficult to form the capacitors in one chip. If the capacitors are prepared outside of the chip, number of parts is increased, a mounted board is complicated, and an area of the mounted board is increased.

That is, as mentioned above, when the capacitors are used in order to cut the direct current, the insertion loss caused by the reactance is generated.

A conduction switching circuit according to the present invention has a first MOSFET, a second MOSFET connected to the first MOSFET via a first node, and a first control terminal connected to the first node. The first MOSFET and the second MOSFET are connected so as to be in series at an ON state. When the first MOSFET and the second MOSFET are an OFF state, the first control terminal applies a voltage to the first node so that capacitance generated in the first MOSFET and the second MOSFET is decreased.

According to the present invention, equivalent interrupting capacitance generated in the first MOSFET and the second MOSFET cuts a direct current from an external terminal. As a result, the capacitance generated in the first MOSFET and the second MOSFET can be decreased by applying a voltage to the first node. Accordingly, a leakage of a high frequency signal can be prevented. On the other hand, at the ON state, the first MOSFET and the second MOSFET act as resistors. As a result, there is no insertion loss caused by a reactance of conductors for cutting the direct current.

A conduction switching circuits block according to the present invention includes; a first conduction switching circuit which is provided between a first end and second end and connects the first end to the second end at the ON state, and a second conduction switching circuit which is provided between ground and the second end and connects the second end to the ground at the OFF state. Each of the first conduction switching circuit and the second conduction switching circuit is the conduction switching circuit mentioned above.

An operation method of a conduction switching circuit according to the present invention is an operation method of a conduction switching circuit having a first MOSFET, a second MOSFET connected to the first MOSFET via a first node, and a first control terminal connected to the first node. The first MOSFET and the second MOSFET is connected so as to be in series at the ON state. The operation method includes; controlling the first MOSFET and the second MOSFET to be the OFF states, and applying a voltage to the first node at the OFF state so that capacitance generated in the first MOSFET and the second MOSFET is decreased.

According to the present invention, a conduction switching circuit, a conduction switching circuit block, and an operating method of the conduction switching circuit are provided, in which an insertion losses caused by a reactance of the capacitors for cutting the direct current is not generated.

### BRIEF DESCRIPTION OF DRAWINGS

FIG. 1 is a circuit diagram showing one example of a MOSFET;

FIG. 2 is a circuit diagram showing an equivalent circuit at an ON state;

FIG. 3 is a circuit diagram showing an equivalent circuit of the MOSFET at an OFF state;

FIG. 4 is a circuit diagram showing an equivalent circuit of the MOSFET at the OFF state;

FIG. 5 is a circuit diagram showing one example of a semiconductor device;

FIG. 6 is a circuit diagram showing an equivalent circuit when the semiconductor device is the OFF state;

FIG. 7 is a circuit diagram showing an equivalent circuit when the semiconductor device is the ON state;

FIG. 8A is a circuit diagram showing a conduction switching circuit according to a first embodiment;

FIG. 8B is a circuit diagram showing a conduction switching circuit according to a variation of the first embodiment;

FIG. 9 is a circuit diagram showing an equivalent circuit at the OFF state according to the first embodiment;

FIG. 10 is an equivalent circuit diagram showing the conduction switching circuit at the ON state;

FIG. 11A is a circuit diagram showing a conduction switching circuit according to a second embodiment;

FIG. 11B is a circuit diagram showing a conduction switching circuit according to a variation of the second embodiment;

FIG. 11C is a circuit diagram showing a conduction switching circuit according to another variation of the second embodiment;

FIG. 12 is an equivalent circuit diagram showing the conduction switching circuit at the OFF state according to the second embodiment;

FIG. 13 is an equivalent circuit diagram showing the conduction switching circuit at the ON state according to the second embodiment;

FIG. 14 is a circuit diagram showing a conduction switching circuit according to a third embodiment;

FIG. 15 is a circuit diagram showing a conduction switching circuit block according to a fourth embodiment; and

FIG. 16 is a circuit diagram showing a conduction switching circuit according to a sixth embodiment.

### DESCRIPTION OF THE PREFERRED EMBODIMENTS

### First Embodiment

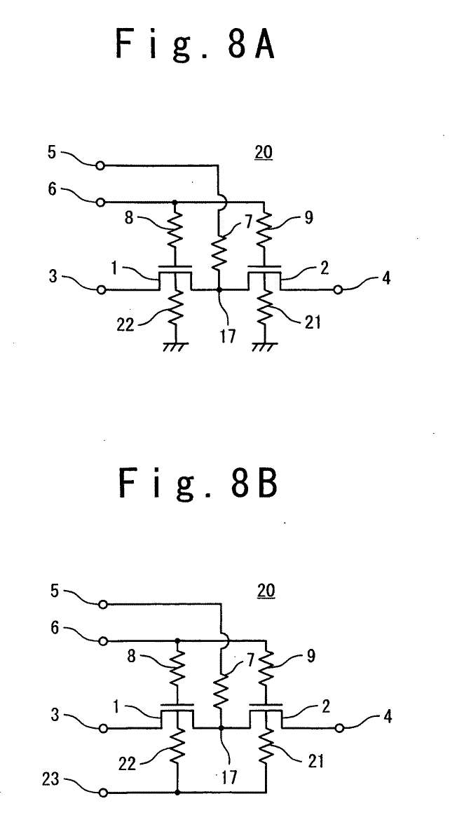

The first embodiment of the present invention will be described below with reference to the drawings. FIG. 8A is a circuit diagram showing a conduction switching circuit 20 according to the present embodiment.

As shown in FIG. 8A, the conduction switching circuit 20 includes a first terminal 3, a second terminal 4, a first MOSFET 1, a second MOSFET 2, a first control terminal 5, and a second control terminal 6. The conduction switching circuit 20 is designed such that a high frequency signal is inputted from the first terminal 3 and outputted to the second terminal 4 at the ON state.

The first MOSFET 1 and the second MOSFET 2 are connected via a first node 17. The first MOSFET 1 and the second MOSFET 2 are provided such that the first terminal 3 and the second terminal 4 are electrically connected at the ON state and the first terminal 3 and the second terminal 4 are electrically separated at an OFF state. Specifically, in the first MOSFET 1, one of a source and a drain is connected to the first terminal 3, and the other one is connected to the first node 17. Also, in the second MOSFET 2, one of a source and a drain is connected to the first node 17, and the other one is connected to the second terminal 4. That is, the first MOSFET 1 and the second MOSFET 2 are electrically connected in series at the ON state.

In the present embodiment, each of the first MOSFET 1 and the second MOSFET 2 is assumed to be an N-channel MOSFET of an enhanced type. Also, in the first MOSFET 1 and the second MOSFET 2, their back gates are grounded via resistors (21, 22), respectively.

The first control terminal 5 is provided to decrease capacitance generated in the first MOSFET 1 and the second MOSFET 2 at the OFF state. The first control terminal 5 is connected to the first node 17 via a resistor 7. A resistance value of the resistor 7 is set so that a signal passing through the first terminal 3 to the second terminal 4 is not leaked to the first control terminal 5 at the ON state (for example, 10 kΩ or more).

The second control terminal 6 is provided to switch the ON state and the OFF state. The second control terminal 6 is connected to a gate of the first MOSFET 1 via a resistor 8. Also, the second control terminal 6 is connected to a gate of the second MOSFET 2 via a resistor 9. Each value of the resistors 8 and 9 is set so that a leakage of the passing signal is prevented (for example, 10 kΩ or more).

An operation of the conduction switching circuit 20 at the OFF state will be described below.

In each of the first MOSFET 1 and the second MOSFET 2, a threshold voltage Vth is assumed to be 0.7 V. It is assumed that a voltage of 0 V is applied to the gate of each MOSFET from the second control terminal 6, and a voltage of +3 V is applied to the first node 17 from the first control terminal 5. At this time, the first MOSFET 1 and the second MOSFET 2 recognize a side of the first terminal 3 and a side of the second terminal 4 as the sources, respectively. For this reason, [Voltage Vgs generated between Gate and Source−Threshold Voltage Vth] becomes [0−0.7=−0.7 V]. Then, channels are insulated. Consequently, the conduction switching circuit 20 becomes the OFF state.

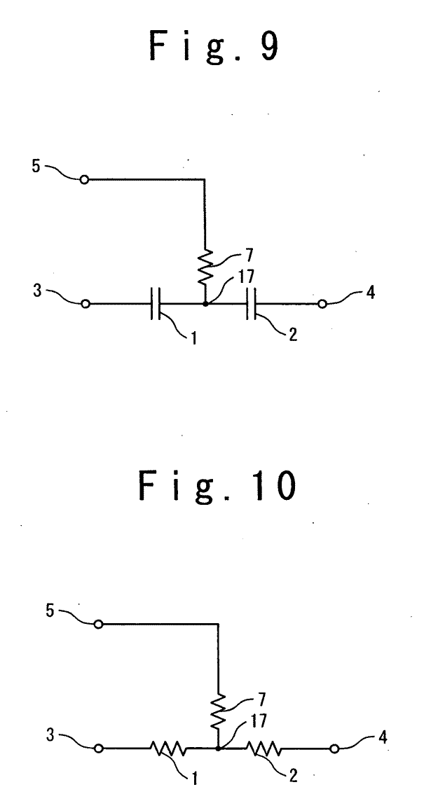

FIG. 9 is an equivalent circuit diagram showing the conduction switching circuit 20 at the off state. As shown in FIG. 9, the first MOSFET 1 and the second MOSFET 2 are represented as capacitors. With the capacitors, the first node 17 is separated from the first terminal 3 and the second terminal 4, from the aspect of the direct current. For this reason, a PN junction included between the drain and the back gate of each MOSFET (1, 2) is reverse-biased by the voltage applied to the first node 17. Consequently, a depletion layer of the PN junction is enlarged, and the capacitance generated between the drain and the back gate is decreased. As the result, the equivalent interrupting capacitance of each MOSFET (1, 2) is decreased, and the leakage of the high frequency signal is prevented.

Next, an operation of the conduction switching circuit 20 at the ON state will be described.

It is assumed that a voltage of +3 V is applied to the gates of the respective MOSFETs (1, 2) from the second control terminal 6, and a voltage of 0 V is applied to the first node 17 from the second control terminal 6. At this time, [Vgs−Vth=+3−0.7=2.3 V] is established, and the channels of the each MOSFET (1, 2) is turned on.

FIG. 10 shows an equivalent circuit of the conduction switching circuit 20 at the ON state. As shown in FIG. 10, the MOSFETs (1, 2) are regarded as resistors. Here, 0 V is applied to the first node 17 from the first control terminal 5, and the resistor 7 is sufficiently large. Thus, the signal passing from the first terminal 3 to the second terminal 4 is not leaked to the first control terminal 5. Also, since capacitor does not exist between the first terminal 3 and the second terminal 4, an insertion loss of the reactance is not generated. That is, according to the present embodiment, the MOSFETs act as the capacitors for cutting the direct current at the OFF state, and the MOSFETs act as the resistors at the ON state. Thus, the leakage of the high frequency signal at the OFF state can be suppressed, without any generation of the insertion loss caused by reactance at the ON state.

Also, according to the present embodiment, the maximum allowable input power can be increased. This point will be described below.

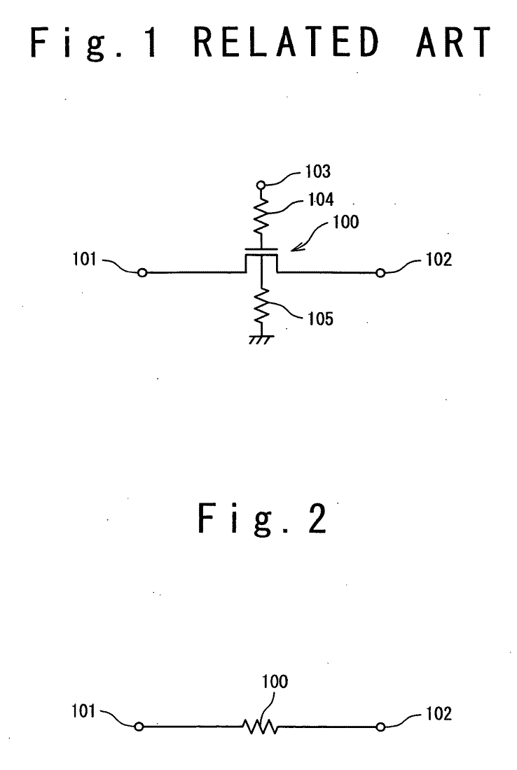

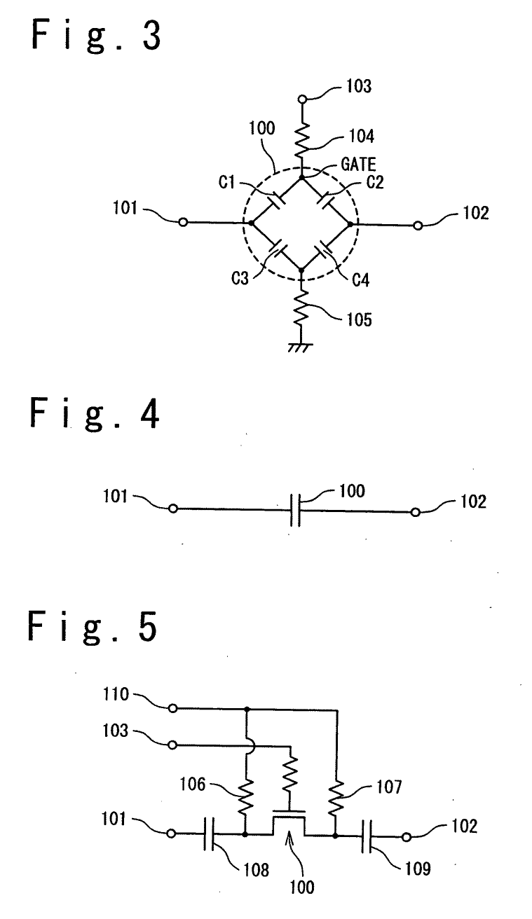

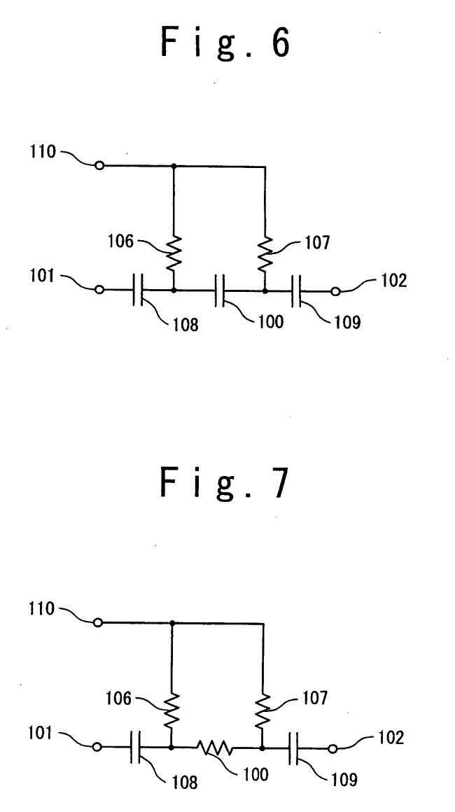

In the MOSFET, typically, the threshold voltage is set to be low in order to decrease a resistance value of a channel at the ON state. For example, in an enhancement type of N-MOSFET operated by a voltage of 3V, the threshold voltage Vth is set to be about 0.7 V. Here, the maximum allowable input power of the MOSFET is described by exemplifying the foregoing MOSFET shown in FIG. 1. In the MOSFET shown in FIG. 1, the second terminal 102 is assumed to be grounded. In this case, if 0 V is applied to the gate from the control terminal 103, a channel of the MOSFET 100 is insulated to be the OFF state. At this time, it is assumed that an alternating voltage having amplitude of 1.4 V is applied to the first terminal 101. At this time, in the MOSFET 100, an alternating voltage whose amplitude is 0.7 V is applied between the gate and the source and between the gate and the drain, by a voltage drop caused by capacitance C1, C2 shown in FIG. 3. When a voltage of a signal applied between the gate and the source is maximum (0.7 V), the voltage applied between the gate and the source is equal to the threshold voltage of the MOSFET 100. Thus, the OFF state is not maintained. That is, in this MOSFET 100, the OFF state is not maintained when the alternating voltage whose amplitude is 1.4 V or more is provided as the input signal. That is, in the MOSFET shown in FIG. 1, the maximum allowable input power is 1.4 V.

On the other hand, in the conduction switching circuit 20 according to the present embodiment, at the OFF state, the first MOSFET 1 and the second MOSFET 2 are represented as the capacitors, as shown in FIG. 9. When the first MOSFET 1 and the second MOSFET 2 are equivalent and an alternating voltage of the high frequency signal is applied to the first terminal 3, the applied alternating voltage is equally divided by the two MOSFETs (1, 2). When the amplitude of the voltage at which the each MOSFET (1, 2) can keep the OFF state is assumed to be 1.4 V or more as mentioned above, the maximum allowable input power of the conduction switching circuit 20 becomes 2.8 V, which is twice of the amplitude of the voltage. That is, according to the present embodiment, the maximum allowable input power can be increased, as compared with the MOSFET shown in FIG. 1.

Also, a gate width of the MOSFET shown in FIG. 1 is represented by Wg and a channel resistance is represented by Rch. At this time, a resistance Ron1 of the MOSFET shown in FIG. 1 at the ON state is represented by Ron1=Rch, as shown in FIG. 2.

On the contrary, in the conduction switching circuit 20 in the present embodiment, only the maximum allowable input power can be increased without increasing the resistance at the ON state, when the gate width of each MOSFET (1, 2) is set to 2×Wg. That is, when the gate width is set to 2×Wg, the resistance at the ON state becomes [Rch/2+Rch/2]=Rch=Ron1. Hence, only the maximum allowable input power can be increased without change of the resistance at the ON state.

As mentioned above, according to the present embodiment, in order to cut the direct current, the MOSFET at the OFF state that is not a capacitor is used. Thus, the leakage of the high frequency signal at the OFF state can be prevented without any generation of the insertion loss at the ON state. In order to reduce the insertion loss at the ON state, a capacitor of the large size is not required, and an area of the conduction switching circuit 20 can be reduced. Also, the maximum allowable input power can be increased without any change of the resistance at the ON state.

By the way, in the present embodiment, the back gate of each MOSFET is grounded through the resistor. However, the back gate of each MOSFET is not necessary to be grounded. FIG. 8B shows a conduction switching circuit 20 according to a variation of the present embodiment. In this conduction switching circuit 20, the back gates of the MOSFETs are connected to a common potential terminal 23, via a resistors (21, 22). At the OFF state, a voltage for decreasing the capacitance generated in each MOSFET is applied to the back gate of the each MOSFET, from the common potential terminal 23. That is, the voltage whose polarity is opposite to that of the voltage applied to the first node 17 (for example, −3 V) is applied to the back gate of each MOSFET. Consequently, in each MOSFET, the capacitance of PN junction between the drain and the back gate is further decreased, and the equivalent interrupting capacitance generated in each MOSFET can be further decreased. Also, the threshold voltage of each MOSFET can be further increased by a bias effect of a substrate. For example, when (−3 V) is applied to the back gate of each MOSFET, the substantial threshold voltage of each MOSFET can be increased from 0.7 V to 1.0 V. As a result, the voltage at which the OFF state is maintained in one MOSFET can be increased from 1.4 V to 2.0 V.

### Second Embodiment

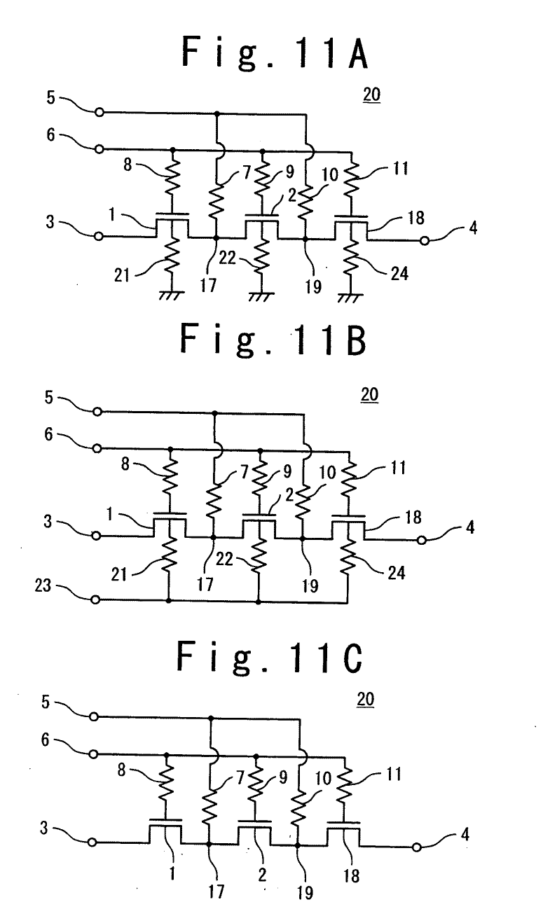

Next, the second embodiment of the present invention will be described below. FIG. 11A is a circuit diagram showing the conduction switching circuit 20 according to the present embodiment. In the conduction switching circuit 20, a third MOSFET 18 is added to the pre-mentioned embodiment. Since the other structures can be same to those of the pre-mentioned embodiment, their detailed explanations are omitted.

As shown in FIG. 11A, the third MOSFET 18 is provided between the second MOSFET 2 and the second terminal 4. One of a source and drain of the third MOSFET 18 is connected to a second node 19, and the other one is connected to the second terminal 4. The source and drain of the second MOSFET 2 is connected to the second node 19, at the side opposite to the first node 17. Also, the gate of the third MOSFET 18 is connected to the second control terminal 6 via a resistor 11. The second node 19 is connected to the first control terminal 5 via a resistor 10. Each of resistance values of the resistors 11 and 10 is set so that the high frequency signal is not leaked at the ON state (for example, 10 kΩ or more).

An operation of the conduction switching circuit 20 at the OFF state will be described. Similarly to the pre-mentioned embodiment, each threshold voltage Vth of the MOSFETs (1, 2 and 18) is assumed to be 0.7 V. A voltage of 0 V is assumed to be applied to the gates of the respective MOSFETs (1, 2 and 18) from the second control terminal 6. Also, it is assumed that a voltage of +3 V is applied to the first node 17 and the second node 19 from the first control terminal 5. At this time, the first MOSFET 1 and the third MOSFET 18 recognize the side of the first terminal 3 and the side of the second terminal 4 as the sources, respectively. The channels of the first MOSFET 1 and the third MOSFET 18 are insulated in accordance with [Vgs−Vth=0−0.7=−0.7 V]. On the other hand, each of the source and the drain in the second MOSFET 2 are biased to +3 V by the first control terminal 5. In accordance with [Vgs−Vth=−3.0−0.7=−3.7 V], the channel of the second MOSFET 2 is insulated.

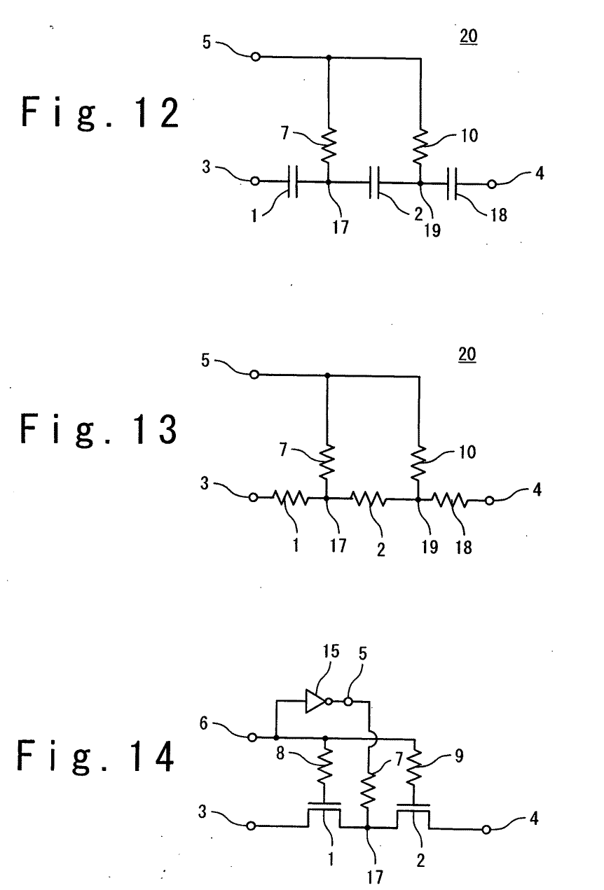

FIG. 12 shows an equivalent circuit of conduction switching circuit 20 at the OFF state. As shown in FIG. 12, the MOSFETs (1, 2 and 18) are represented as capacitors. In the second MOSFET 2, the capacitance formed between the source and the back gate and the capacitance formed between the drain and the back gate are decreased by voltages applied to the first node 17 and the second node 19. Also, in the first MOSFET 1 and the third MOSFET 18, the capacitance formed between the drain and the back gate is decreased by the voltages applied to the first node 17 and the second node 19. Consequently, similarly to the pre-mentioned embodiment, the capacitance generated in the MOSFETs at the OFF state can be decreased, and the leakage of the high frequency signal is prevented.

Also, in the second MOSFET 2, [Vgs−Vth=−3.0−0.7=−3.7 V] is established. Thus, in the second MOSFET 2, the OFF state can be maintained when the amplitude of the alternating voltage signal is less than 7.4 V. Here, for example, it is assumed that a ratio of the gate width between the first MOSFET, the second MOSFET, and the third MOSFET is set to 5:1:5. In this time, at the ON state, the ratio of the equivalent interrupting capacitance between the first MSOFET, second MOSFET, and third MOSFET becomes 5:1:5. Here, it is assumed that the second terminal 4 is grounded and the alternating voltage signal is applied to the first terminal 3. In this case, at the OFF state, the ratio of a voltage drop by the equivalent interrupting capacitance becomes 1:5:1, between the first MOSFET, the second MOSFET and the third MOSFET. That is, most of the voltage drop can be assigned to the second MOSFET 2. It is assumed that the alternating voltage signal having is 9.8 V in amplitude is inputted from the first terminal 3. At this time, the voltage drops of the first MOSFET, the second MOSFET, and third MOSFET become 1.4 V, 7.0 V, and 1.4 V, respectively. In all of the respective MOSFETs (1, 2 and 18), the OFF state can be maintained. That is, the maximum allowable input power of the conduction switching circuit 20 becomes 9.8 V.

Japanese Patent Publication (JP-P 2006-121217A) describes the technique whose object is to improve the maximum allowable input power. In JP-P 2006-121217A, a technique is described, in which the maximum allowable input power can be 7.4 V in an enhancement type n-channel MOSFET having a threshold voltage of 0.7 V. As mentioned above, in the conduction switching circuit 20 according to the present embodiment, the maximum allowable input power of 9.8 V can be obtained, and the maximum allowable input power is further improved, as compared with the technique described in JP-P 2006-121217A.

Next, an operation of the conduction switching circuit 20 at the ON state will be described. It is assumed that a voltage of +3 V is applied to the gates of the respective MOSFETs (1, 2 and 18) from the second control terminal 6. Also, it is assumed that a voltage of 0 V is applied to the first node 17 and the second node 19 from the first control terminal 5. At this time, the channels of the respective MOSFETs (1, 2 and 18) are turned on, in accordance with [Vgs−Vth=+3−0.7=2.3 V]. FIG. 13 shows an equivalent circuit of the conduction switching circuit 20 at the ON state. As shown in FIG. 13, the respective MOSFETs (1, 2 and 18) become the ON states and are represented by the usual channel resistors. Since the capacitance is not generated between the first terminal 3 and the second terminal 4, an insertion loss caused by a reactance is not generated.

As mentioned above, according to the present embodiment, the leakage of the high frequency signal at the off state can be prevented without any generation of the insertion loss at the on state caused by a reactance of capacitors. Also, the maximum allowable input power can be extremely improved.

FIG. 11B is a circuit diagram showing the conduction switching circuit 20 according to a variation in the present embodiment. As indicated in the variation, the back gates of the respective MOSFETs (1, 2 and 18) may be respectively connected to the common potential terminal 23, via the resistors (21, 22 and 24). Similarly to the variation in the first embodiment, a voltage whose polarity is opposite to that of the first node 17 is applied from the common potential terminal 23. Consequently, the capacitance generated in each MOSFET can be further decreased.

There is a MOSFET that does not have a terminal for the back gate. According to the present embodiment, the maximum allowable input power can be improved, even for the MOSFET that does not have a back gate. FIG. 11C is the circuit diagram showing the conduction switching circuit 20 according to another variation in the present embodiment. In this variation, the respective MOSFETs (1, 2 and 18) are assumed to be SOI (Silicon On Insulator) MOSFETs of a full-depletion type. The SOI MOSFET of the full-depletion type is a MOSFET manufactured by an SOI technique and does not have a back gate terminal. The other structures are equal to those of the present embodiment. In this conduction switching circuit 20, the threshold voltage of the second MOSFET 2 is determined by the voltages applied to the first node 17 and the second node 19. For this reason, for example, when +3 V is applied to the respective nodes (17, 19), [Vgs−Vth=3.0−0.7=−3.7 V] is established in the second MOSFET 2. As a result, similarly to the present embodiment, the maximum allowable input power can be improved up to 9.8 V.

### Third Embodiment

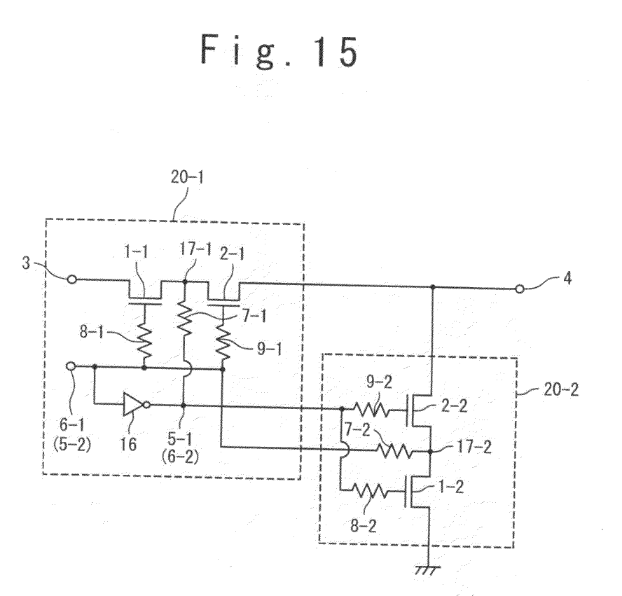

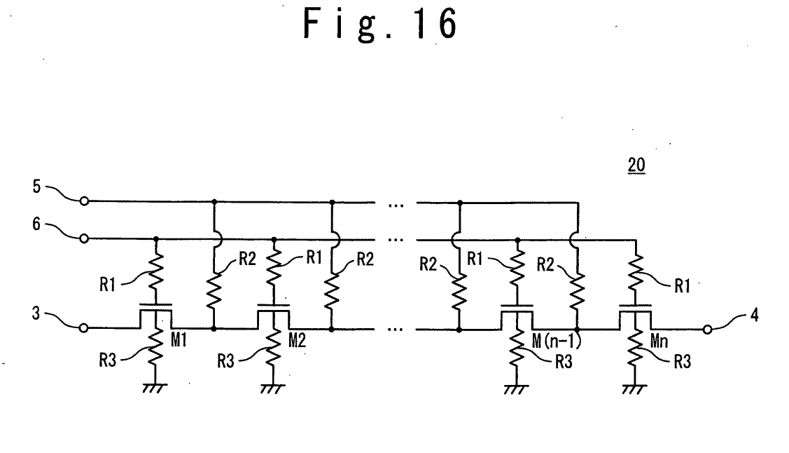

The third embodiment of the present invention will be described below. FIG. 14 is a circuit diagram showing the conduction switching circuit 20 according to the present embodiment. As shown in FIG. 14, an inverter circuit 15 is added in the conduction switching circuit 20. The other structures can be same to those of the pre-mentioned embodiments. Thus, their detailed explanations are omitted.

In the inverter-circuit 15, an input end is connected to the second control terminal 6. Also, an output end of the inverter circuit 15 is connected to the first node 17 via the resistor 7. When the output end of the inverter circuit 15 is assumed to be the first control terminal 5, the first control terminal 5 and the second control terminal 6 are said to be connected via the inverter circuit 15. Consequently, a voltage whose logic level is opposite to that of the first node 17 is applied to the gates of the MOSFETs (1, 2).

According to the present embodiment, an effect same to that in the pre-mentioned embodiments can be obtained. Additionally, since the inverter circuit 15 is used, the number of the substantial control terminals can be one, and a configuration can be simple.

### Fourth Embodiment

The fourth embodiment of the present invention will be described below. In the present embodiment, a conduction switching circuit block is described, which has two conduction switching circuits each of which is described in the first embodiment. FIG. 15 is a circuit diagram showing the conduction switching circuit block according to the present embodiment.

As shown in FIG. 15, the conduction switching circuit block according to the present embodiment includes a first conduction switching circuit block 20-1 and a second conduction switching circuit block 20-2.

The first conduction switching circuit block 20-1 is configured to switch whether the first terminal 3 is connected to the second terminal 4 or not. On the other hand, the second conduction switching circuit block 20-2 is configured to switch whether the second terminal 4 is grounded or not.

Also, a second control terminal 6-1 in the first conduction switching circuit block 20-1 functions as a first control terminal 5-2 in the second conduction switching circuit block 20-2. That is, the second control terminal 6-1 is connected to the gates of the respective MOSFETs (1-1, 2-1) in the first conduction switching circuit block 20-1 and also connected to a first node 17-2 in the second conduction switching circuit block 20-2.

Also, the second control terminal 6-1 is connected a first control terminal 5-1 via an inverter circuit 16. The first control terminal 5-1 also functions as a second control terminal 6-2 in the second conduction switching circuit block 20-2. That is, the first control terminal 5-1 is connected to a first node 17-1 in the first conduction switching circuit block 20-1 via a resistor 7-1 and also connected to the gates of the respective MOSFETs (1-2, 2-2) in the second conduction switching circuit block 20-2.

In the conduction switching circuit block according to the present embodiment, when the first conduction switching circuit block 20-1 is the ON state, the second conduction switching circuit block 20-2 is the OFF state. On the other hand, when the second conduction switching circuit block 20-2 is the OFF state, the second conduction switching circuit block 20-2 becomes the ON state, and the second terminal 4 is grounded. As mentioned above, the conduction switching circuit block according to the present embodiment acts as 1-input-1-output switching circuit block that has a so-called shunt function. In the two conduction switching circuits (20-1, 20-2), similarly to the pre-mentioned embodiments, the leakage of the high frequency signal at the OFF state can be prevented without any generation of the insertion loss caused by the reactance of the capacitors, and the maximum allowable input power can be improved. Also, since the inverter circuit 16 is used, the circuits block can be controlled by one control signal.

Also, when a plurality of conduction switching circuits blocks according to the present embodiment are prepared and a decoder logic circuit block are combined, it is possible to obtain all n-input-m-output circuit groups for switching high frequency signal.

### Fifth Embodiment

Next, the fifth embodiment will be explained. In the present embodiment, the threshold voltages Vth of the first and third MOSFETs are changed from those of the second embodiment (see FIG. 11A). The other structures can be same to those of the second embodiment. Thus, their detailed explanations are omitted.

In the second embodiment, at the OFF state, channels of the first MOSFET 1 and the third MOSFET 18 are insulated, according to “Vgs−Vth=0−0.7=−0.7V”. On the other hand, a channel of the second MOSFET 2 is insulated, according to “Vgs−Vth=−3.0−0.7=−3.7V”. As the results, maximum allowable voltages of the first MOSFET 1, the second MOSFET 2, and the third MOSFET 18 become 1.4V, 7.4V, and 1.4V, respectively.

Here, it is assumed that a ratio of a gate width is set to be “5:1:5”, between the first MOSFET 1, the second MOSFET 2, and the third MOSFET 18.

Also, it is assumed that +3V is applied to the gate of the each MOSFET (1,2,18) by the second control terminal 6 and 0V is applied to the first node 17 and the second node 19 by the first control terminal 5, at the ON state. The each MOSFET becomes ON state, according to “Vgs−Vth=+3−0.7=2.3V”. Here, it is assumed that the gate width of the each MOSFET (1,2,18) is set so that channel resistance of the each MOSFET is equal to that of a MOSFET whose gate width is Wg (Ron1=Rch). In this case, the gate widths of the first MOSFET 1, the second MOSFET 2, and the third MOSFET 18 become 7×Wg, 1.4×Wg, and 7×Wg, respectively. At the OFF state, a ratio of voltage drops becomes “1.4:7.0:1.4”, between the first MOSFET 1, the second MOSFET 2 and the third MOSFET 18. According to the second embodiment, considering that the maximum allowable voltages of the first MOSFET 1, the second MOSFET 2, and the third MOSFET 18 are respectively 1.4V, 7.4V and 1.4V, the maximum allowable input voltage is increased to 9.8V, according to “1.4V+7.0V+1.4V=9.8V”. On the other hand, a total of the gate widths is increased to 15.4×Wg, according to “7×Wg+1.4×Wg+7×Wg=15.4×Wg”.

That is, in the second embodiment, a ratio, of the maximum allowable voltage of the second MOSFET 2 (7.4V) to that in each of the first MOSFET 1 and the third MOSFET 18 (1.4V) is large. Accordingly, if the gate widths of the first, second, and third MOSFET are decided so that a voltage corresponding to the maximum allowable voltage of the each MOSFET is distributed to the each MOSFET, the gate width in each of the first and third MOSFET becomes about 5.3 times of that in the second MOSFET 2, according to “7.4/1.4=5.3”. As a result, an area size of a whole circuit is increased.

On the other hand, in the present embodiment, the threshold voltages of the first MOSFET 1 and the third MOSFET 18 are respectively set to 1.0V. Also, the threshold voltage of the second MOSFET 2 is set to 0.7V.

In the present embodiment, at the OFF state, the channels of the first MOSFET 1 and the third MOSFET 18 are insulated, according to “Vgs−Vth=0−1.0=−1.0V”. The channel of the second MOSFET 2 is insulated, according to “Vgs−Vth=−3.0−0.7=−3.7V”. That is, the maximum allowable voltages of the first MOSFET 1, the second MOSFET 2, and the third MOSFET 18 become 2.0V, 7.4V, and 2.0V, respectively. In each of the first MOSFET 1 and the third MOSFET 18, the maximum allowable voltage is increased, because the threshold voltage is increased. However, in each of the first MOSFET 1 and the third MOSFET 18, the channel resistance at the ON state is also increased. In each of the first MOSFET 1 and the third MOSFET 18, an increase rate of the channel resistance is in inverse proportion to “Vgs−Vth” at the ON state and becomes 1.15 times of that in the second embodiment, according to “(3.0−0.7/3.0−1.0)=2.0/2.3=1.15”.

Here, it is assumed that the gate width of the each MOSFET is set so that a voltage corresponding to the maximum allowable voltage of the each MOSFET is distributed to the each MOSFET at the OFF state. Moreover, it is assumed that +3V is applied to the gate of the each MOSFET (1,2,18) by the second control terminal 6 and 0V is applied to the first and second node (19, 17) by the first control terminal 5, at the ON state. At this time, the each of the first MOSFET 1 and the third MOSFET 18 becomes conduction state, according to “Vgs−Vth=+3−1.0=2.0V”. The channel of the second MOSFET 2 becomes conduction state, according to “Vgs−Vth=+3−0.7=2.3V”. It is assumed that the gate width of the each MOSFET is set so that the channel resistance of the each MOSFET becomes equal to that of a MOSFET whose gate width is Wg (Ron1=Rch). That is, the gate widths of the first MOSFET 1, the second MOSFET 2, and the third MOSFET 18 are set to 5.8×Wg, 1.66×Wg, and 5.8×Wg, respectively. In this case, in the first MOSFET 1, the second MOSFET 2, and the third MOSFET 18 which are in an insulating state, the voltage drops become 2.0V, 7.0V, and 2.0V, respectively. The maximum allowable input voltage of a whole circuit becomes 11.0V, and is increased compared with that of the second embodiment. Also, a total gate width becomes 13.2×Wg, according to “5.8×Wg+1.66×+5.8×Wg=13.2×Wg”, and can be decreased compared with that of the second embodiment.

As mentioned above, according to the present embodiment, the threshold voltages of the first MOSFET 1 and the third MOSFET 18 are changed to 1.0V from 0.7V. As a result, the maximum allowable voltages of the first MOSFET 1 and the third MOSFET 18 are increased to 2.0V from 1.4V. A ratio of the maximum allowable voltage in the second MOSFET 2 (7.4V) to that in each of the first and the third MOSFET is reduced to 3.7 times (7.4V/2.0V=3.7) from 5.3 times (7.4V/1.4V=5.3). As a result, when a voltage corresponding to the maximum allowable voltage of the each MOSFET is distributed to the each MOSFET, the gate widths of the first MOSFET 1 and the third MOSFET 18 can be about 3.7 times of that in the second MOSFET 2, according to “7.4V/2.0V=3.7”. Accordingly, compared with the second embodiment, the area size of the whole circuit can be reduced.

As mentioned above, according to the present embodiment, the maximum allowable input voltage can be further increased without increasing the channel resistance at the ON state, and the area size of the circuit can be reduced, because the threshold voltage in each of the first MOSFET 1 and the third MOSFET is different from that in the second MOSFET 2.

### Sixth Embodiment

Next, the sixth embodiment will be described. FIG. 16 is a circuit diagram showing a conduction switching circuit 20 according to the present embodiment. The conduction switching circuit 20 according to the present embodiment includes n (n shows a number that is more than 3) MOSFETs (M1 to Mn), which are provided between the first end 3 and the second end 4. The n MOSFETs are connected in series. In each of n MOSFETs, the gate is connected to the second control terminal 6 via a resistor R1. Also, an each node provided between two neighboring MOSFETs is connected to the first control terminal 5, via a resistor R2. In the each MOSFET, a back gate is grounded via a resistor R3. The other structures can be same to those of the second embodiment. Thus, their detailed explanations are omitted.

According to the present embodiment, an effect same to that in the pre-mentioned embodiments can be obtained. That is, at the OFF state, the first control terminal 5 applies voltages to the plurality of nodes each of which is provided between two neighboring MOSFETs so that the capacitance generated in the each MOSFET is decreased. As a result, the leakage of the high frequency signal at the OFF state can be prevented without generating any insertion losses. Also, the maximum allowable input power can be increased significantly.

The maximum allowable input power will be specifically explained below. Among the n MOSFETs, the MOSFET connected to the first end 3 will be described as a first MOSFET (M1). Among the n MOSFETs, the MOSFET connected to the second end 4 will be described as a third MOSFET (Mn). Also, an each of the plurality of the MOSFETs provided between the first MOSFET (M1) and the third MOSFET (Mn) will be described as a second MOSFET.

It is assumed that 0V is applied to the second control terminal 6 and +3V is applied to the first control terminal 5. In this case, channels of the first MOSFET (M1) and the third MOSFET (Mn) are insulated, according to “Vgs−Vth=0−0.7=−0.7V”. The each second MOSFET is insulated, according to “Vgs−Vth=−3.0−0.7=−3.7V”. The maximum allowable voltages of the first MOSFET (M1), the each second MOSFET, and the third MOSFET (Mn) become 1.4V, 7.4, and 1.4V, respectively. Here, it is assumed that a ratio of the gate widths between the first MOSFET (M1), the each second MOSFET, and the third MOSFET (Mn) is set to “5:1:5”. In this case, the each MOSFET (M1 to Mn) becomes a conduction state, according to “Vgs−Vth=+3−0.7=2.3V”. Here, it is assumed that the gate width of the each MOSFET (M1 to Mn) is set so that channel resistance in the each MOSFET (M1 to Mn) is equal to that in a MOSFET whose gate width is Wg (Ron1=Rch). In this case, the gate widths of the first MOSFET (M1), the each second MSOFET, and the third MOSFET (Mn) become (5n−8)Wg, (n−1.6)Wg, and (5n−8)Wg, respectively. At this time, the maximum allowable input voltage of the conduction switching circuit 20 becomes “1.4×2+7.4×(n−2)”V. In a case that the first control terminal is not biased and the gate width of the each MOSFET is set to be equal, the maximum allowable input voltage becomes “1.4×n”V. Compared with this case, the maximum allowable input voltage in the conduction switching circuit 20 according to the present invention can be increased.

### Seventh Embodiment

Next, the seventh embodiment will be described. In the present embodiment, the threshold voltage of the each MOSFET (M1 to Mn) is changed from that in the sixth embodiment. The other structures can be same to those of the sixth embodiment. Thus, their detailed explanations are omitted.

In the present embodiment, the threshold voltage in each of the first MOSFET (M1) and the third MOSFET (Mn) is set to 1.0V, and that in the each second MOSFET is set to 0.7V. In this case, at the off state, the channel in each of the first MOSFET (M1) and the third MOSFET (Mn) is insulated, according to “Vgs−Vth=0−1.0=−1.0V”. Also, the channel of the each second MOSFET is insulated, according to “Vgs−Vth=−3.0−0.7=−3.7V”.

That is, the maximum allowable voltages of the first MOSFET (M1), the each second MOSFET, and the third MOSFET become 2.0V, 7.4V, and 2.0V, respectively. In the each MOSFET (M1 and Mn), the maximum allowable voltage is increased by an increase of the threshold voltage. However, in each of the first MOSFET (M1) and the third MOSFET (Mn), the channel resistance at the ON state is also increased. In each of the first MOSFET (M1) and the third MOSFET (Mn), an increase rate of the channel resistances is in inverse proportion to “Vgs−Vth” at the ON state and becomes 1.15 times of that in the sixth embodiment, according to “(3.0−0.7/3.0−1.0)=2.0/2.3=1.15”.

Here, it is assumed that the gate width of the each MOSFET (M1 to Mn) is set so that a voltage corresponding to the maximum allowable voltage of the each MOSFET is distributed to the each MOSFET. Moreover, it is assumed that +3V is applied to the gate of the each MOSFET (M1 to Mn) by the second control terminal 6 and 0V is applied to the each node by the first control terminal 5 at the ON state. In this case, the each of the first MOSFET (M1) and the second MOSFET (Mn) becomes conduction state, according to “Vgs−Vth=+3.0−1.0=2.0V”. The each second MOSFET becomes conduction state, according to “Vgs−Vth=+3.0−0.7=2.3V”. In this case, it is assumed that the gate width of the each MOSFET (M1 to Mn) is set such that the channel resistance at the ON state of the each MOSFET becomes equal to that of a MOSFET whose gate width is Wg. In this case, the gate widths of the first MOSFET, the each second MOSFET, and the third MOSFET become (3.5n−4.7)Wg, (n−1.4)Wg, and (3.5n−4.7)Wg. Compared with the sixth embodiment, a total gate width can be decreased. Also, the maximum allowable input voltage of the conduction switching circuit becomes (2.0×2+7.4×(n−2))V. According to the present embodiment, the maximum allowable input voltage can be increased, compared with that in the sixth embodiment ((1.4×2+7.4×(n−2))V).

As mentioned above, the first to seventh embodiments are described. These embodiments are not independent of each other. These embodiments can be combined with each other if there is not a contradiction. For example, in the second embodiment, the first control terminal and the second control terminal may be connected through the inverter circuit. Also, as each conduction switching circuit 20 in the fourth embodiment, the conduction switching circuit according to the second embodiment may be used.

What is claimed is:

1. A conduction switching circuit, comprising:
a first MOSFET;
a second MOSFET connected to said first MOSFET via a first node; and
a first control terminal connected to said first node;
wherein said first MOSFET and said second MOSFET are provided so as to be electrically connected in series at an ON state, and
said first control terminal is configured to apply a voltage to said first node so that capacitance generated in said first MOSFET and said second MOSFET is decreased when said first MOSFET and said second MOSFET are an OFF state.

2. The conduction switching circuit according to claim 1, further comprising, a third MOSFET which is connected to said second MOSFET via a second node,
wherein said second MOSFET and said third MOSFET are connected so as to be in series at the ON state, and
said first control terminal is connected to said second node and configured to apply a voltage to said second node so that capacitance of said second MOSFET and said third MOSFET is decreased when said first MOSFET, said second MOSFET, and said third MOSFET are the OFF state.

3. The conduction switching circuit according to claim 1, wherein said first control terminal is connected to said first node via a first resistor whose size is set so that a signal passing through said first node is not leaked to said first control terminal at the ON state.

4. The conduction switching circuit according to claim 1, wherein back gates of said first MOSFET and said second MOSFET are respectively grounded via a resistor of 10 KΩ or more.

5. The conduction switching circuit according to claim 1, wherein back gates of said first MOSFET and said second MOSFET are respectively connected to a common potential terminal which is different from the ground, via a resistor of 10 KΩ or more.

6. The conduction switching circuit according to claim 5, wherein said common potential terminal is configured to apply a voltage to said back gates of said first MOSFET and said second MOSFET so that capacitance generated in said first MOSFET and said second MOSFET is decreased at the OFF state.

7. The conduction switching circuit according to claim 1, wherein each of said first MOSFET and said second MOSFET has three terminals of source, drain, and gate, and does not have a back gate terminal.

8. The conduction switching circuit according to claim 1, further comprising, a second control terminal which is connected to a gate of said first MOSFET and a gate of said second MOSFET and applies a voltage to said gates of said first MOSFET and said second MOSFET to control the ON/OFF states of said first MOSFET and said second MOSFET.

9. The conduction switching circuit according to claim 8, wherein said first control terminal and said second control terminal are connected via an inverter circuit.

10. A conduction switching circuit block comprising;
a first conduction switching circuit which is provided between a first end and a second end and connects said first end and said second end at the ON state; and
a second conduction switching circuit which is provided between the ground and said second end and connects said second end to the ground at the ON state;
wherein each of said first conduction switching circuit and said second conduction switching circuit is the conduction switching circuit according to claim 1.

11. The conduction switching circuit block according to claim 10, wherein said first control terminal in said first conduction switching circuit is connected to said first control terminal in said second conduction switching circuit, via an inverter circuit.

12. An operation method of a conduction switching circuit having a first MOSFET, a second MOSFET connected to said first MOSFET via a first node, and a first control terminal connected to said first node, wherein said first MOSFET and said second MOSFET are connected in series at the ON state, comprising:
controlling said first MOSFET and said second MOSFET to be the OFF states;
applying a voltage to said first node so that parasitic capacitance generated in said first MOSFET and said second MOSFET is decreased when said first MOSFET and said second MOSFET are the OFF state.

13. The conduction switching circuit according to the claim 2, wherein a gate width of said first MOSFET and a gate width of said third MOSFET are larger than a gate width of said second MOSFET.

14. A conduction switching circuit, comprising:
a plurality of MOSFETs provided between a fist end and a second end so as to be electrically connected in series at an ON state; and
a first control terminal connected to a plurality of nodes existing between said plurality of MOSFETs:
wherein said first control terminal is configured to apply a voltage to each of said plurality of nodes so that capacitance generated in said plurality of MOSFETs is decreased when said plurality of MOSFETs are OFF state,
said plurality of MOSFETs include;
a first MOSFET connected to said first end;
a third MOSFET connected to said second end; and
a plurality of second MOSFET provided between said first MOSFET and said third MOSFET, and
a gate width of said first MOSFET and a gate width of said third MOSFET are larger than a gate width of each of said plurality of second MOSFETs.

15. A conduction switching circuit, comprising:
a plurality of MOSFETs provided between a fist end and a second end so as to be electrically connected in series at an ON state; and
a first control terminal connected to a plurality of nodes existing between said plurality of MOSFETs:
wherein said first control terminal is configured to apply a voltage to each of said plurality of nodes so that capacitance generated in said plurality of MOSFETs is decreased when said plurality of MOSFETs are OFF state,
said plurality of MOSFETs include;
a first MOSFET connected to said first end;
a third MOSFET connected to said second end; and
a plurality of second MOSFET provided between said first MOSFET and said third MOSFET, and
threshold voltages of said first MOSFET and said third MOSFET are set so as to be different from a threshold voltage of each of said plurality of second MOSFETs.
